(19) United States
(12) Patent Application Publication
(10) Pub. No.: US 2010/0287336 A1
(43) Pub. Date: Nov. 11, 2010

(54) EXTERNAL I/O SIGNAL AND DRAM REFRESH SIGNAL SYNCHRONIZATION METHOD AND ITS CIRCUIT

(75) Inventors: Shinsuke TANAKA, Kyoto (JP); Daigo SENOO, Osaka (JP)

Correspondence Address: MCDERMOTT WILL & EMERY LLP, 600 13TH STREET, N.W., WASHINGTON, DC, 20005-3096, US

(73) Assignee: PANASONIC CORPORATION, Osaka (JP)

(21) Appl. No.: 12/843,500

(22) Filed: Jul. 26, 2010

Related U.S. Application Data
(63) Continuation of application No. PCT/JP2008/002972, filed on Oct. 20, 2008.

(30) Foreign Application Priority Data
Feb. 26, 2008 (JP) 2008-044529

(51) Int. Cl. G06F 12/08; H03K 19/177

(52) U.S. Cl. 711/106; 326/39; 711/E12.022

(57) ABSTRACT

In an LSI that determines timing of DRAM refresh by a refresh timer to synchronize an external I/O signal and DRAM refresh timing with each other, a circuit configuration capable of controlling a value of the refresh timer by a CPU at arbitrary timing is employed. Alternatively, a circuit configuration capable of controlling the value of the refresh timer at arbitrary timing by an external terminal, or a circuit configuration capable of controlling the refresh timing directly from the external terminal without through the refresh timer.

### CROSS-REFERENCE TO RELATED APPLICATION

This is a continuation of PCT International Application PCT/JP2008/002972 filed on Oct. 20, 2008, which claims priority to Japanese Patent Application No. 2008-044529 filed on Feb. 26, 2008. The disclosures of these applications including the specifications, the drawings, and the claims are hereby incorporated by reference in their entirety.

### BACKGROUND ART

The present invention relates to timing control of a DRAM (dynamic random access memory) refresh in a semiconductor circuit that has connection between a CPU (central processing unit) and the DRAM, and that is operated when the CPU accesses the DRAM.

A conventional technique has an object to enhance DRAM-accessing efficiency by controlling DRAM refresh timing so that access to the DRAM and refresh do not come into conflict with each other.

In the conventional technique, a cycle of the DRAM refresh is previously set in a refresh timer, and whenever the refresh timer finishes counting the cycle, a DRAM refresh command is issued, but only when DRAM access is being executed when the refresh should be issued, the issue of the refresh command at this time is stopped, higher priority is given to the access to the DRAM, refresh commands are collectively issued as many as the issue-stopped times of the refresh at the next and subsequent refresh timing so that the access to the DRAM is not hindered by the issue of the DRAM refresh command, thereby achieving the object (see Japanese Patent Publication No. 2004-192721).

### SUMMARY

According to the conventional technique, the timing of the external I/O signal and the timing of the DRAM refresh can not be synchronized with each other.

There is a system where an external determining device is connected to an LSI (large-scale integrated circuit) having connection between a CPU and a DRAM, the external determining device supplying an input signal to the LSI, determining an output signal from the LSI after fixed time and concluding a next operation according to the output signal. In such a system, even when the same LSI executes the same instruction, timing of the execution of the instruction is deviated depending upon a timing relation between the DRAM refresh and the input and output signals and as a result, timing of the output signal that is sent to the external determining device is deviated and finally, there is a problem such that the external determining device does not execute the assumed operation.

This problem will be explained in detail with reference to FIGS. 7 and 8.

FIG. 7 is a diagram showing a conventional system configuration. In the system shown in FIG. 7, an external determining device 105 is connected to an LSI 100. The external determining device 105 is a tester of, for example, the LSI 100. The LSI 100 includes a CPU 101, a refresh timer 102, a DRAM controller 103, a DRAM 104, and a PLL (phase-locked loop) circuit 113. Reference numbers 10 to 13 represent I/O terminals of the external determining device 105, and reference numbers 20 to 23 represent external terminals of the LSI 100.

The refresh timer 102 is a down counter that operates in synchronization with an LSI operation clock 114 having the maximum value of N, and the refresh timer 102 issues a refresh timer underflow signal 111 when the count value becomes “0”.

In the system shown in FIG. 7, the following series of operations (1) to (5) are continuously and repeatedly carried out without issuing a hardware reset signal 109 to the LSI 100 from the completion of execution of an instruction to the start of execution of the next instruction in the CPU 101.

(1) After the external determining device 105 releases the hardware reset signal 109 with respect to the LSI 100, supply of the stable LSI operation clock 114 is started from the PLL circuit 113.

(2) Thereafter, data required for operating the CPU 101 is supplied from the external determining device 105 to the DRAM 104 as a download signal 116.

(3) Next, an input signal 106 is supplied from the external determining device 105 to the LSI 100.

(4) The CPU 101 accesses data that has been downloaded to the DRAM 104, and starts a designated operation.

(5) When given time T is elapsed after the input signal 106 is supplied from the external determining device 105, the external determining device 105 determines an output signal 107 from the LSI 100.

That is, the input signal 106 is supplied from the external determining device 105 to the LSI 100 and the operation of the LSI 100 is started, and after the fixed time T, the external determining device 105 determines the output signal 107 that is output as a result of operation of the LSI 100, and based on a result thereof, a next operation of the external determining device 105 is concluded. These series of operations are continuously executed a plurality of times without executing the hardware reset of the LSI 100.

The DRAM controller 103 issues a DRAM access command 117 in accordance with an access signal 115 from the CPU 101. Contents of access to the DRAM 104 executed by the CPU 101 upon reception of the input signal 106 from the external determining device 105 have the same contents every time.

FIG. 8 is a timing chart of internal operation of the LSI 100 shown in FIG. 7 and of input and output signals between the external determining device 105 and the LSI 100. At time t1, the supply of the LSI operation clock 114 is started. At time t3, the first input signal 106 from the external determining device 105 to the LSI 100 is supplied. At time t4, the external determining device 105 determines the first output signal 107 from the LSI 100. At time t6, the second input signal 106 is supplied from the external determining device 105 to the LSI 100. At time t7, the external determining device 105 determines the second output signal 107 from the LSI 100.

As shown in FIG. 8, when the first instruction is executed (between time t3 and time t4), there is no conflicts between the DRAM refresh command 112 and the DRAM access command 117, but when the second instruction is executed (between time t6 and time t7), a conflict is generated between the DRAM refresh command 112 and the DRAM access command 117.

The DRAM refresh command 112 is periodically issued when the count value of the refresh timer 102 becomes 0, but the count value of the refresh timer 102 when the input signal 106 is supplied from the external determining device 105 to the LSI 100 varies in some cases between the execution of the first instruction and the execution of the second and subsequent instructions. Therefore, timing at which the DRAM access command 117 is issued and timing at which the DRAM refresh command 112 is issued are different from each other in some cases between the execution of the first instruction and the execution of the second and subsequent instructions. In FIG. 8, the first count value (at time t3) is A, and the second count value (at time t6) is C, and A≠C.

For this reason, during the series of operations, a conflict state between the DRAM refresh and the access to the DRAM 104 from the CPU 101 varies between the execution of the first instruction and the execution of the second and subsequent instructions and as a result, times of conflict also varies in some cases. FIG. 8 shows an example in which the number of conflicts of the second time is larger than that of the first time.

Generally, whenever a conflict between the DRAM refresh and the access to the DRAM 104 from the CPU 101 occurs, timing of the access execution of the CPU 101 to the DRAM 104 is delayed as compared with a case having no conflicts.

Therefore, when the number of conflicts between the DRAM refresh and the access to the DRAM 104 from the CPU 101 varies between the first time and the second and subsequent times as shown in FIG. 8, time required until the series of operations is completed after the start of the operation of the case having the larger number of conflicts is increased as compared with time of the case having the smaller number of conflicts. As a result, timing of the output signal 107 from the LSI 100 to the external determining device 105 is deviated between the first time and the second and subsequent times. Therefore, the output signal 107 can not be determined at the right timing in the external determining device 105 that determines the output signal 107 from the LSI 100 when the fixed time T is elapsed after the input signal 106 is supplied to the LSI 100, and there is a problem that the next operation can not be executed precisely in some cases. In the example shown in FIG. 8, erroneous determination is made by the delay of the output signal 107 at time t7.

In the series of operations, an object to always equalize the conflict state between the DRAM refresh command that is issued during the series of operations and the access to the DRAM 104 from the CPU 101 is achieved by issuing the hardware reset signal 109 to the LSI 100 every time between the completion of execution of an instruction by the CPU 101 and the start of execution of a next instruction.

However, in the series of operations, if the hardware reset signal 109 is issued to the LSI 100 every time between the completion of execution of the instruction by the CPU 101 and the start of execution of the next instruction, waiting time elapsed until the PLL circuit 113 can supply stable LSI operation clock 114 and waiting time elapsed until download of data required for operating the CPU 101 with respect to the DRAM 104 from the external determining device 105 is completed are generated before the execution of the next instruction is started. As a result, time required for completing the series of operations is increased.

The present disclosure proposes a circuit configuration and its method for easily solving the above problem.

According to the present disclosure, the above problem is solved by synchronizing timing of the external I/O signal and timing of the DRAM refresh, thereby uniquely determining the timing of the external I/O signal and the timing of the DRAM refresh when the same LSI is executing the same instruction.

It is possible to employ the following two specific methods for synchronizing the timing of the external I/O signal and the timing of the DRAM refresh.

(1) To employ a semiconductor circuit that determines timing of the DRAM refresh by a refresh timer, in which a value of the refresh timer is controlled at arbitrary timing by a CPU or an external terminal.

(2) To employ a circuit configuration capable of directly controlling the timing of the DRAM refresh from an external terminal without through a refresh timer.

When an external determining device which externally supplies an input signal to an LSI having connection between a CPU and a DRAM and determines an output signal from the LSI after fixed time to conclude a next operation is connected to the LSI, it is possible to constitute a system that is not affected adversely, at all, by variation between timing of an external I/O signal and timing of DRAM refresh.

### BRIEF DESCRIPTION OF THE DRAWINGS

FIG. 1 is a block diagram of a system according to a first embodiment of the present invention;

FIG. 2 is a timing chart of internal operation of an LSI shown in FIG. 1, and of input and output signals between an external determining device and the LSI;

FIG. 3 is a block diagram of a system according to a second embodiment of the invention;

FIG. 4 is a timing chart of internal operation of an LSI shown in FIG. 3, and of input and output signals between an external determining device and the LSI;

FIG. 5 is a block diagram of a system according to a third embodiment of the invention;

FIG. 6 is a timing chart of internal operation of an LSI shown in FIG. 5, and of input and output signals between an external determining device and the LSI;

FIG. 7 is a block diagram of a conventional system; and

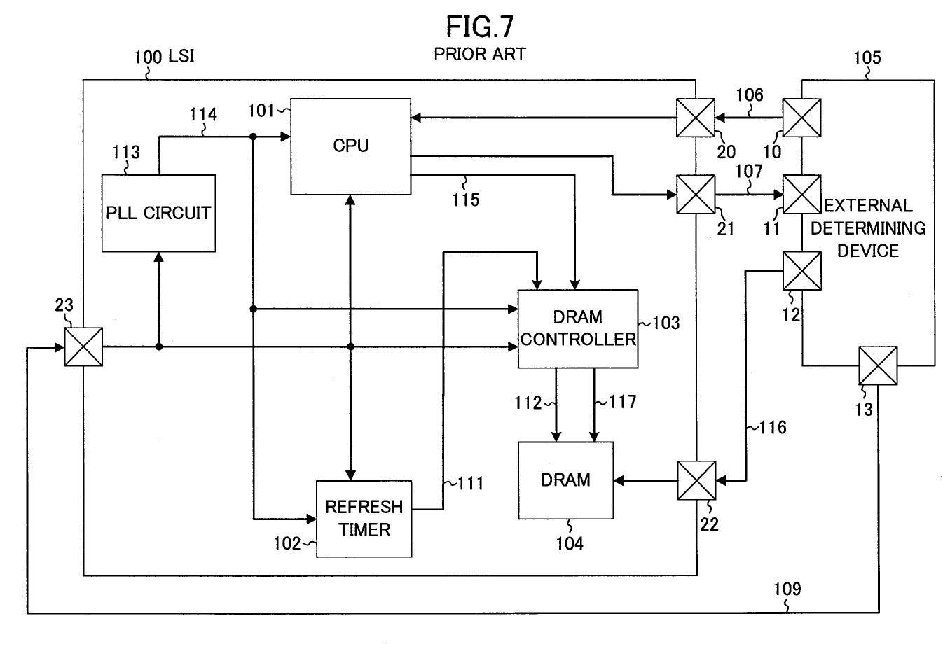

FIG. 8 is a timing chart of internal operation of an LSI shown in FIG. 7, and of input and output signals between an external determining device and the LSI.

### DESCRIPTION OF EMBODIMENTS

### First Embodiment

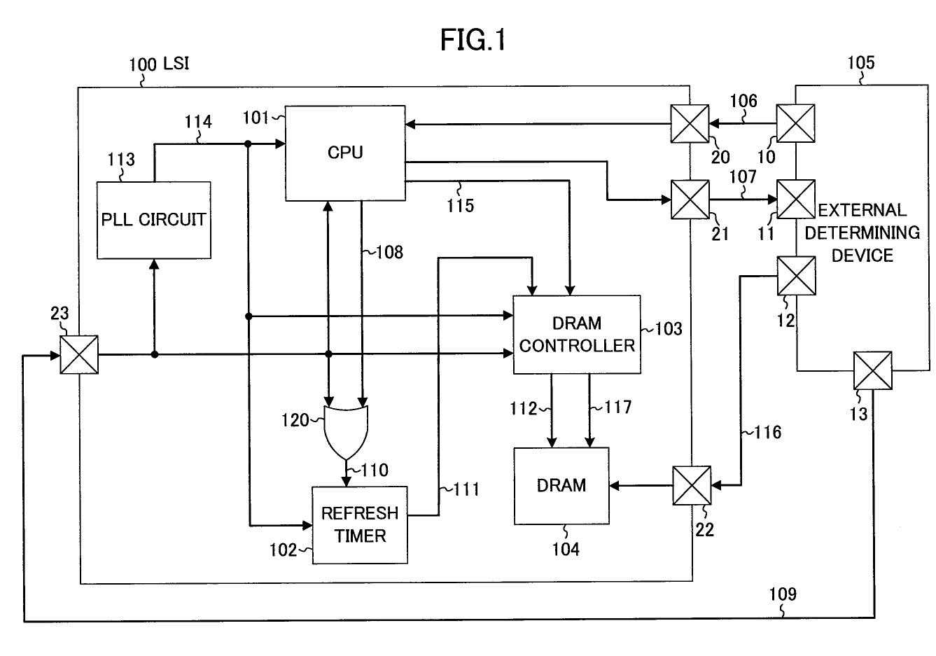

FIG. 1 is a block diagram of a system according to a first embodiment of the present invention. In the system shown in FIG. 1, an OR circuit 120 is provided in an LSI 100 so that a refresh timer reset signal 110 is produced by a hardware reset signal 109 from an external determining device 105 or a refresh timer initialization command 108 from a CPU 101, and a refresh timer 102 is initialized to a certain value (“0” for example) by the refresh timer reset signal 110.

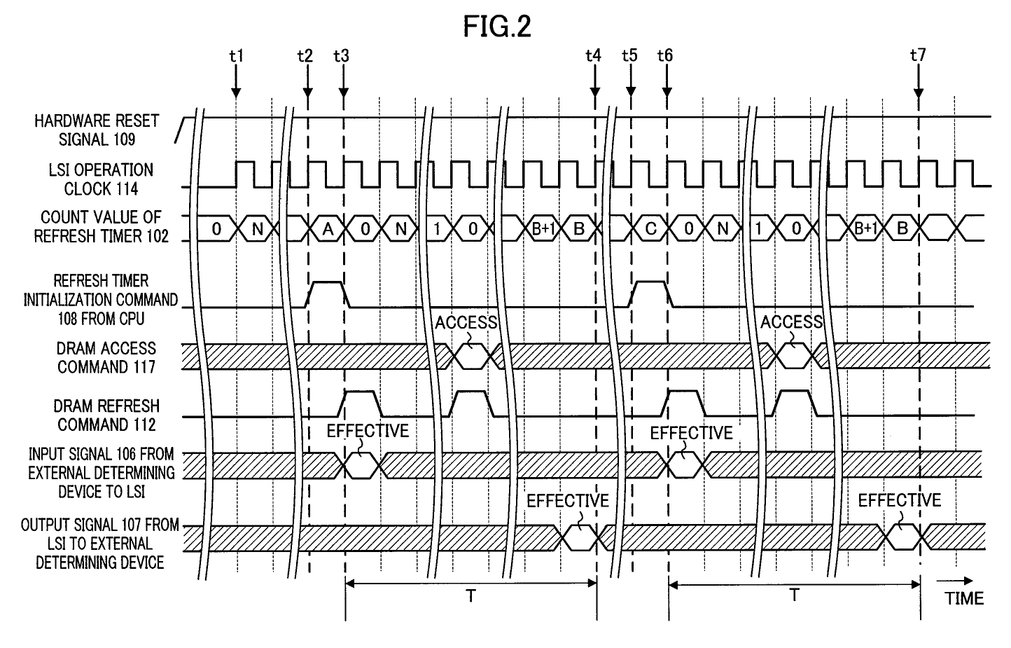

FIG. 2 is a timing chart of internal operation of the LSI 100 shown in FIG. 1, and of input and output signals between the external determining device 105 and the LSI 100. As shown in FIG. 2, the refresh timer initialization command 108 is issued from the CPU 101 at time t2 and t5 immediately before an input signal 106 is supplied from the external determining device 105 to the LSI 100 at time t3 and t6. With this, a count value of the refresh timer 102 when the input signal 106 is supplied from the external determining device 105 to the LSI 100 at the time of execution of a first instruction (time t3) and at the time of execution of second and subsequent instructions (time t6) can always be brought into “0” and can match with each other.

Therefore, during the series of operations, the number of conflicts between the DRAM refresh and the access to the DRAM 104 from the CPU 101 can always be made the same. Since timing delay of instruction fetch and instruction execution in the CPU 101 as a result of conflicts can always be the same between the first time and the second and subsequent times, time required for the series of operations is always the same between the first time and the second and subsequent times. As a result, timing at which the output signal 107 is supplied from the LSI 100 to the external determining device 105 is always the same timing, and the external determining device 105 always determines the output signal 107 at precise timing (time t4 and t7). Therefore, it is possible to prevent a malfunction of the external determining device 105.

### Second Embodiment

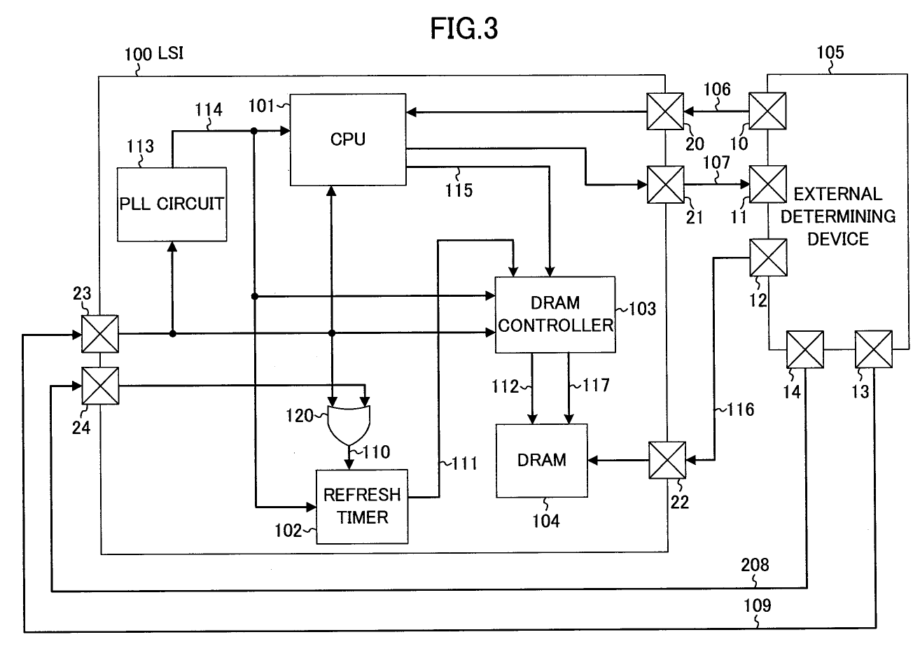

FIG. 3 is a block diagram of a system according to a second embodiment of the invention. In the system shown in FIG. 3, the refresh timer 102 is initialized to a certain value (“0” for example) by the hardware reset signal 109 from the external determining device 105 or by a refresh timer initialization signal 208 from the external determining device 105. The hardware reset signal 109 is a reset signal for the operation of the entire LSI 100, but the refresh timer initialization signal 208 is a reset signal that is effective only for a count value of the refresh timer 102, and functions of these signals are different from each other in this aspect. A reference number 14 represents an I/O terminal that is added to the external determining device 105, and a reference number 24 represents an external terminal that is added to the LSI 100.

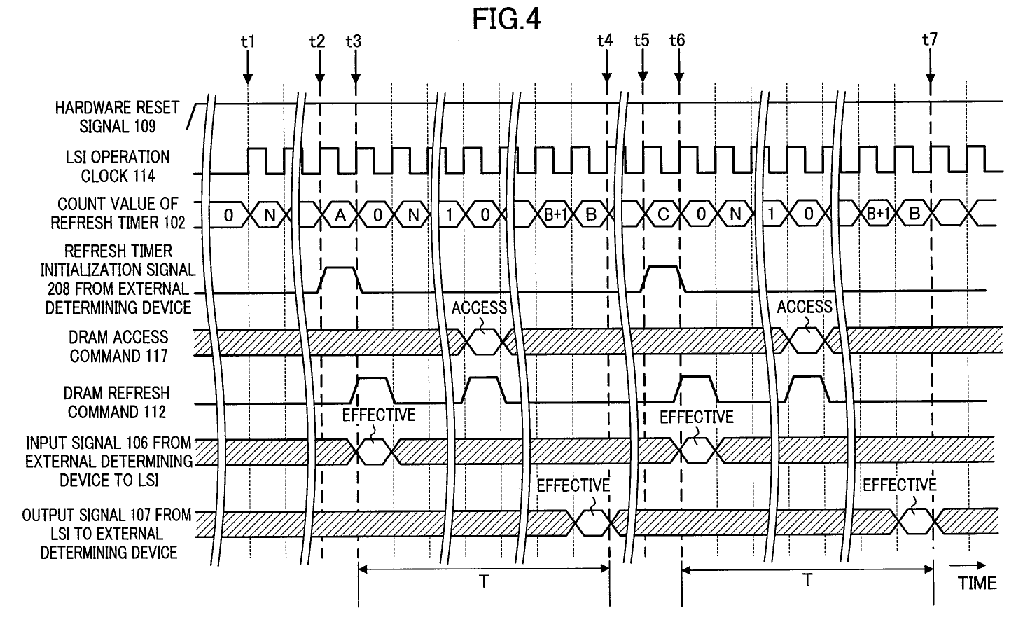

FIG. 4 is a timing chart of internal operation of the LSI 100 shown in FIG. 3, and of input and output signals between the external determining device 105 and the LSI 100. As shown in FIG. 4, the external determining device 105 issues the refresh timer initialization signal 208 to the LSI 100 at time t2 and t5 immediately before the external determining device 105 supplies the input signal 106 to the LSI 100 at time t3 and t6. With this, a count value of the refresh timer 102 when the external determining device 105 supplies the input signal 106 to the LSI 100 can always be set to “0” and match at the time of the first instruction execution (time t3) and at the time of second and subsequent instruction execution (time t6). Therefore, the same advantage as the first embodiment can be obtained.

### Third Embodiment

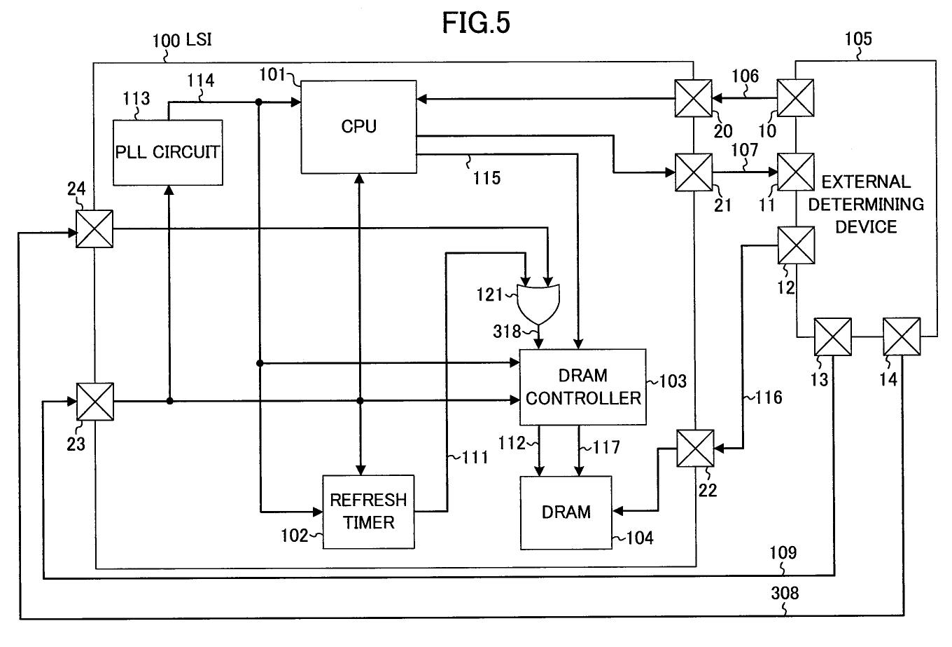

FIG. 5 is a block diagram of a system according to a third embodiment of the invention. According to the system shown in FIG. 5, an OR circuit 121 is provided in the LSI 100 so that a DRAM refresh timing signal 318 is produced by the refresh timer underflow signal 111 from the refresh timer 102 or a DRAM refresh requesting signal 308 from the external determining device 105, and issue of the DRAM refresh command 112 is directly controlled by the DRAM refresh timing signal 318. A reference number 14 represents an I/O terminal added to the external determining device 105, and a reference number 24 represents an external terminal added to the LSI 100.

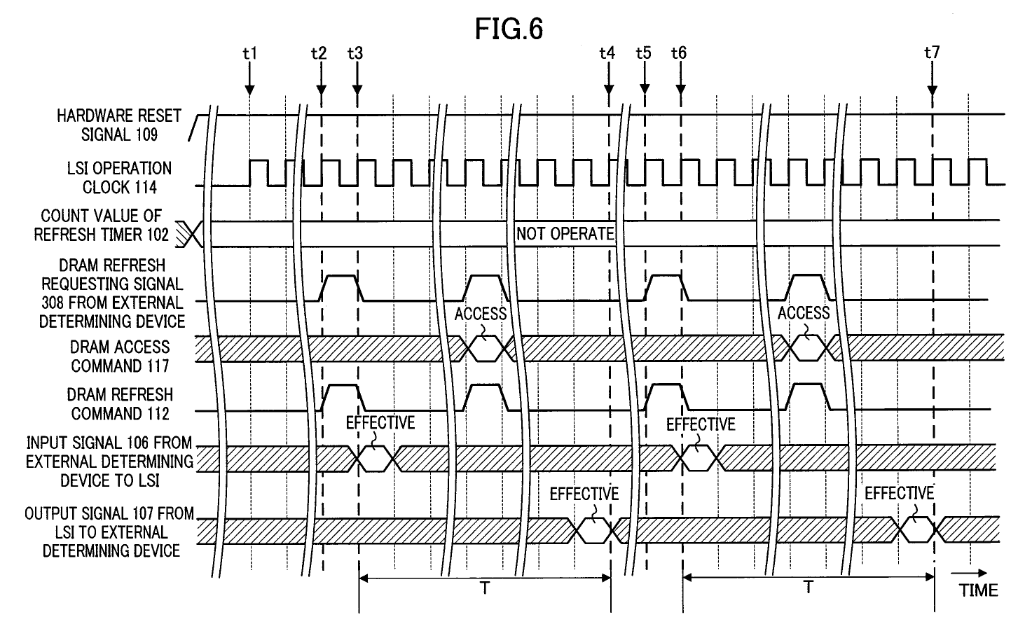

FIG. 6 is a timing chart of internal operation of the LSI 100 shown in FIG. 5, and of input and output signals between an external determining device 105 and the LSI 100. As shown in FIG. 6, the operation of the refresh timer 102 is stopped so that the refresh timer underflow signal 111 is not issued from the refresh timer 102. In this state, the DRAM refresh requesting signal 308 is issued from the external determining device 105 to the LSI 100 at appropriate timing such as time t2 and t5 immediately before the input signal 106 is supplied from the external determining device 105 to the LSI 100 at time t3 and t6. With this, during the series of operations, the number of conflicts between the DRAM refresh and the access to the DRAM 104 from the CPU 101 can always be set to the same. Therefore, the same advantage as the first embodiment can be obtained.

If the techniques explained in each of the above embodiments are employed, waiting time is not generated between the completion of execution of the instruction and the start of execution of the next instruction in the CPU 101. Therefore, it is possible to shorten the time required until the series of operations is completed as compared with a case where a method of issuing the hardware reset signal 109 to the LSI 100 every time between the completion of execution of the instruction and the start of execution of the next instruction in the CPU 101 is employed.

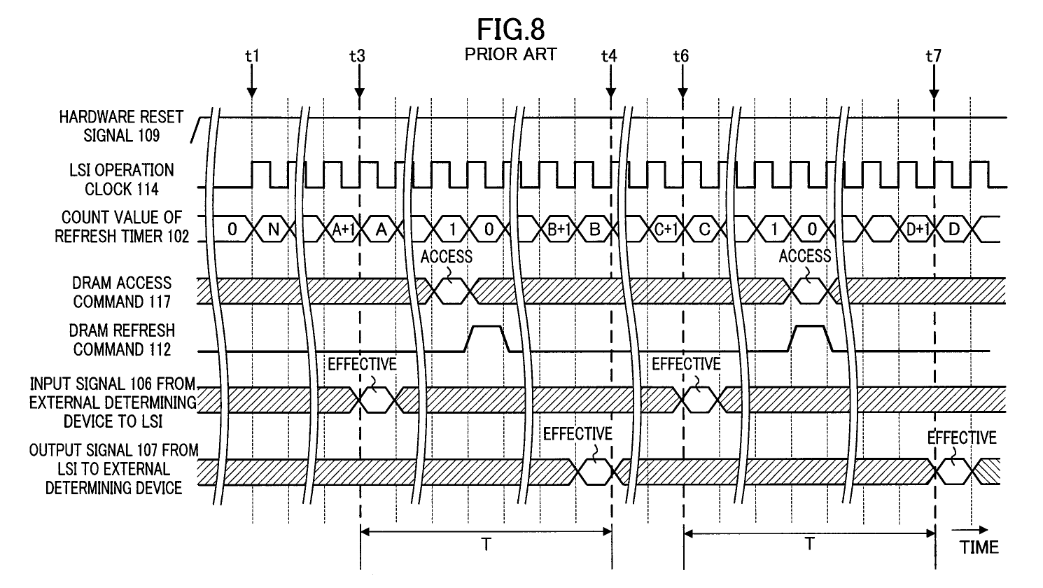

Although the same instruction is executed a plurality of times continuously without issuing the hardware reset signal 109 to the LSI 100 in this example, when instructions having different contents are continuously executed without issuing the hardware reset signal 109, if the function of the present disclosure is not utilized, the problem described referring to FIG. 8 may occur.

A case where two instructions A and B are continuously executed without issuing the hardware reset signal 109 to the LSI 100 will be considered. When the function of the present disclosure is not utilized, the number of times of refresh generated during execution of the instructions may vary in some cases between a case where the instruction A and the instruction B are executed in this order and a case where the instruction B and the instruction A are executed in this order. Therefore, the external determining device 105 may not operate properly in some cases. Such a problem can also be solved by the disclosure.

The external determining device 105 is a semiconductor tester, that is, a tester, for example, but programmable hardware such as an FPGA (field programmable gate array) or CPLD (complex programmable logic device) may be connected to the LSI 100 as the external device instead of the external determining device 105.

If the semiconductor circuit of the present disclosure is mounted on the LSI, a tester is connected to the LSI and the LSI is tested, the test can be carried out continuously a plurality of times without issuing a reset to the LSI. Therefore, time required until the operation of the CPU is started from the release of the reset of the LSI for each of the tests can be shortened. As a result, time requires for the tests can be shortened, and test cost can be reduced.

What is claimed is:

1. A semiconductor circuit comprising:
a DRAM;
a CPU that executes access with respect to the DRAM;
a DRAM controller that issues a DRAM access command in accordance with an access signal from the CPU, and that periodically issues a DRAM refresh command;
a plurality of external terminals; and
a refresh timer that determines issue timing of the DRAM refresh command, wherein
the refresh timer is initialized to a certain value by a command from the CPU,
I/O signals from some of the plurality of external terminals and the DRAM refresh command are synchronized with each other, and
when the CPU executes the access having the same content with respect to the DRAM a plurality of times, instruction executing time is the same every time.

2. A semiconductor circuit comprising:
a DRAM;
a CPU that executes access with respect to the DRAM;
a DRAM controller that issues a DRAM access command in accordance with an access signal from the CPU, and that periodically issues a DRAM refresh command;
a plurality of external terminals; and
a refresh timer that determines issue timing of the DRAM refresh command, wherein
a signal is input from one of the plurality of external terminals to initialize the refresh timer to a certain value,
I/O signals from some of the plurality of external terminals and the DRAM refresh command are synchronized with each other, and
when the CPU executes the access having the same content with respect to the DRAM a plurality of times, instruction executing time is the same every time.

3. A semiconductor circuit comprising:
a DRAM;
a CPU that executes access with respect to the DRAM;
a DRAM controller that issues a DRAM access command in accordance with an access signal from the CPU, and that periodically issues a DRAM refresh command;
a plurality of external terminals; and
a refresh timer that determines issue timing of the DRAM refresh command, wherein
a signal is input from one of the plurality of external terminals to directly control issue of the DRAM refresh command without using the refresh timer,
I/O signals from some of the plurality of external terminals and the DRAM refresh command are synchronized with each other, and
when the CPU executes the access having the same content with respect to the DRAM a plurality of times, instruction executing time is the same every time.

4. The semiconductor circuit of claim 1, wherein
operation time concerning the I/O signals when the CPU executes access having the same content with respect to the DRAM the plurality of times is always uniquely determined irrespective of start timing of instruction execution.

5. The semiconductor circuit of claim 2, wherein
operation time concerning the I/O signals when the CPU executes access having the same content with respect to the DRAM the plurality of times is always uniquely determined irrespective of start timing of instruction execution.

6. The semiconductor circuit of claim 3, wherein
operation time concerning the I/O signals when the CPU executes access having the same content with respect to the DRAM the plurality of times is always uniquely determined irrespective of start timing of instruction execution.

7. A system comprising:
the semiconductor circuit of claim 1; and
an external device that supplies an input signal to the semiconductor circuit from one of the plurality of external terminals, thereby operating the semiconductor circuit.

8. The system of claim 7, wherein
the external device is an external determining device that supplies the input signal to the semiconductor circuit, determines an output signal from the semiconductor circuit after fixed time, and concludes subsequent operation.

9. The system of claim 7, wherein
the external device is a semiconductor tester.

10. The system of claim 7, wherein
the external device is programmable hardware such as an FPGA and a CPLD.

11. A system comprising:
the semiconductor circuit of claim 2; and
an external device that supplies an input signal to the semiconductor circuit from one of the plurality of external terminals, thereby operating the semiconductor circuit.

12. The system of claim 11, wherein
the external device is an external determining device that supplies the input signal to the semiconductor circuit, determines an output signal from the semiconductor circuit after fixed time, and concludes subsequent operation.

13. The system of claim 11, wherein
the external device is a semiconductor tester.

14. The system of claim 11, wherein
the external device is programmable hardware such as an FPGA and a CPLD.

15. A system comprising:
the semiconductor circuit of claim 3; and
an external device that supplies an input signal to the semiconductor circuit from one of the plurality of external terminals, thereby operating the semiconductor circuit.

16. The system of claim 15, wherein
the external device is an external determining device that supplies the input signal to the semiconductor circuit, determines an output signal from the semiconductor circuit after fixed time, and concludes subsequent operation.

17. The system of claim 15, wherein
the external device is a semiconductor tester.

18. The system of claim 15, wherein
the external device is programmable hardware such as an FPGA and a CPLD.
